(19) United States
(12) Patent Application Publication
(10) Pub. No.: US 2010/0212713 A1
(43) Pub. Date: Aug. 26, 2010

(54) Thermoelectric Conversion Module Component, Thermoelectric Conversion Module, and Method for Producing the Aforementioned

(75) Inventors: Masahiro Sasaki, Yasu-shi (JP); Takanori Nakamura, Omihachiman-shi (JP)

Correspondence Address: DICKSTEIN SHAPIRO LLP, 1633 Broadway, NEW YORK, NY, 10019, US

(73) Assignee: Murata Manufacturing Co., Ltd.

(21) Appl. No.: 12/776,736

(22) Filed: May 10, 2010

Related U.S. Application Data
(63) Continuation of application No. PCT/JP2008/070598, filed on Nov. 12, 2008.

(30) Foreign Application Priority Data
Nov. 14, 2007 (JP) 2007-295754

(51) Int. Cl. H01L 35/02; B32B 38/04; H01L 35/34

(52) U.S. Cl. 136/233; 156/250; 156/60; 156/253; 136/201

(57) ABSTRACT

A thermoelectric conversion module component includes a laminate formed of a plurality of stacked thermoelectric elements each including a unit circuit having repeated pn junction pairs that extend meanderingly and that are formed of p-type thermoelectric material layers and n-type thermoelectric material layers arranged so as to be alternately connected to each other on a surface of an insulating layer, and oblique joint surfaces at which electrodes are led out of the laminate. The oblique joint surfaces are such that a plurality of the thermoelectric conversion module components are electrically connected by contacting the surfaces with each other to form a ring. A thermoelectric conversion module includes a plurality of the thermoelectric conversion module components connected to each other to form a ring.

### CROSS REFERENCE TO RELATED APPLICATIONS

The present application is a continuation of International Application No. PCT/JP2008/070598, filed Nov. 12, 2008, which claims priority to Japanese Patent Application No. JP2007-295754, filed Nov. 14, 2007, the entire contents of each of these applications being incorporated herein by reference in their entirety.

### FIELD OF THE INVENTION

The present invention relates to thermoelectric conversion module components, thermoelectric conversion modules, and methods for producing the thermoelectric conversion module components and the thermoelectric conversion modules.

### BACKGROUND OF THE INVENTION

An example of conventional thermoelectric conversion modules is a “thermoelectric generator” described in Japanese Unexamined Patent Application Publication No. 5-219765 (Patent Document 1). This generator includes a plurality of long block p-type thermoelectric elements and a plurality of n-type thermoelectric elements alternately arranged in the radial direction of a cylinder, in which adjacent thermoelectric elements are electrically connected with electrodes to form a zigzag pattern, resulting in a series structure in which the p- and n-type elements are alternately connected.

Patent Document 1: Japanese Unexamined Patent Application Publication No. 5-219765

Such a thermoelectric conversion module described in Patent Document 1 is produced by assembling the plural block p- and n-type thermoelectric elements. It is necessary to form gaps between the thermoelectric conversion elements in order to provide electrical insulation, except for portions to be electrically connected. Thus, the thermoelectric conversion module has a gappy structure, which is fragile by external impact and unreliable.

The plural p- and n-type thermoelectric conversion elements are alternately connected with the electrodes. However, it is impossible to hold the entire structure only by the presence of the electrodes arranged at joints. Thus, an insulating substrate or the like are required to hold the thermoelectric conversion module, leading to a complicated structure.

### SUMMARY OF THE INVENTION

It is an object of the present invention to provide a simply-structured, reliable thermoelectric conversion module that is not easily broken by impact, a thermoelectric conversion module component as a part used for the assembly of the module, and methods for producing the thermoelectric conversion module and the thermoelectric conversion module component.

To achieve the foregoing object, a thermoelectric conversion module component according to the present invention includes a laminate formed of a plurality of stacked thermoelectric elements each including a unit circuit having repeated pn junction pairs that extend meanderingly and that are formed of p-type thermoelectric material layers and n-type thermoelectric material layers arranged so as to be alternately connected to each other on a surface of an insulating layer. The thermoelectric conversion module component further includes oblique joint surfaces at which electrodes are led out of the laminate, the oblique joint surfaces being such that a plurality of the thermoelectric conversion module components are connected by contacting the surfaces with each other to form a ring as a whole and are electrically connected to each other.

According to the present invention, It is possible to easily establish electrical connection between the thermoelectric conversion module components through the joint surfaces and to form a structure in which the thermoelectric conversion module components are supported by each other using the joint surfaces, thereby assembling the reliable thermoelectric conversion module having a simple ring structure that is not easily broken by impact as a whole.

### BRIEF DESCRIPTION OF DRAWINGS

FIG. 1 is a perspective view of a first example of a thermoelectric conversion module component according to a first embodiment of the present invention.

FIG. 2 is an explanation view of a first step in a method for producing a thermoelectric conversion module component according to the first embodiment of the present invention.

FIG. 3 is an explanation view of a second step in the method for producing a thermoelectric conversion module component according to the first embodiment of the present invention.

FIG. 4 is an explanation view of a third step in the method for producing a thermoelectric conversion module component according to the first embodiment of the present invention.

FIG. 5 is a perspective view of a first example of a thermoelectric conversion module according to the first embodiment of the present invention.

FIG. 6 is an explanation view of the shape of the thermoelectric conversion module according to the first embodiment of the present invention.

FIG. 7 is a perspective view of a second example of the thermoelectric conversion module component according to the first embodiment of the present invention.

FIG. 8 is a perspective view of a second example of the thermoelectric conversion module according to the first embodiment of the present invention.

FIG. 9 is a perspective view of a third example of the thermoelectric conversion module according to the first embodiment of the present invention.

FIG. 10 is an explanation view of a first example of external terminals of the thermoelectric conversion module according to the first embodiment of the present invention.

FIG. 11 is an explanation view of a second example of the external terminals of the thermoelectric conversion module according to the first embodiment of the present invention.

FIG. 12 is an exploded view of a thermoelectric conversion module component according to the first embodiment of the present invention, the thermoelectric conversion module component being such that a connection in series is established with via holes therein.

FIG. 13 is an explanation view of a third example of the external terminals of the thermoelectric conversion module according to the first embodiment of the present invention.

FIG. 14 is a perspective view of a state in which the thermoelectric conversion module according to the first embodiment of the present invention is installed around a pipe.

FIG. 15 is a perspective view of a first example of a thermoelectric conversion module component according to a second embodiment of the present invention.

FIG. 16 is a perspective view of a first example of a thermoelectric conversion module according to the second embodiment of the present invention.

FIG. 17 is a perspective view of a second example of the thermoelectric conversion module component according to the second embodiment of the present invention.

FIG. 18 is a perspective view of a second example of the thermoelectric conversion module according to the second embodiment of the present invention.

FIG. 19 is a perspective view of a third example of the thermoelectric conversion module component according to the second embodiment of the present invention.

FIG. 20 is a perspective view of a first example of a thermoelectric conversion module component according to a third embodiment of the present invention.

FIG. 21 is an explanation view of the shape of the thermoelectric conversion module component according to the third embodiment of the present invention.

FIG. 22 is an explanation view of a first step in a method for producing a thermoelectric conversion module component according to the third embodiment of the present invention.

FIG. 23 is an explanation view of the outline of an inner circuit in the course of the method for producing a thermoelectric conversion module component according to the third embodiment of the present invention.

FIG. 24 is an explanation view of a second step in the method for producing a thermoelectric conversion module component according to the third embodiment of the present invention.

FIG. 25 is an explanation view of a modification of the second step in the method for producing a thermoelectric conversion module component according to the third embodiment of the present invention.

FIG. 26 is a perspective view of a first example of a thermoelectric conversion module according to the third embodiment of the present invention.

FIG. 27 is a perspective view of a second example of the thermoelectric conversion module component according to the third embodiment of the present invention.

FIG. 28 is a perspective view of a second example of the thermoelectric conversion module according to the third embodiment of the present invention.

FIG. 29 is a perspective view of a third example of the thermoelectric conversion module component according to the third embodiment of the present invention.

FIG. 30 is a perspective view of a state in which the thermoelectric conversion module according to the third embodiment of the present invention is installed around a pipe.

FIG. 31 is an explanation view of a first step in a method for producing a thermoelectric conversion module according to a fourth embodiment of the present invention.

FIG. 32 is an explanation view of a second step in the method for producing a thermoelectric conversion module according to the fourth embodiment of the present invention.

FIG. 33 is an explanation view of a third step in the method for producing a thermoelectric conversion module according to the fourth embodiment of the present invention.

FIG. 34 is an explanation view of a fourth step in the method for producing a thermoelectric conversion module according to the fourth embodiment of the present invention.

FIG. 35 is an explanation view of a modification of the method for producing a thermoelectric conversion module according to the fourth embodiment of the present invention.

FIG. 36 is an exploded view of a thermoelectric conversion module component according to a fifth embodiment of the present invention.

FIG. 37 is a perspective view of a first example of the thermoelectric conversion module component according to the fifth embodiment of the present invention.

FIG. 38 is a perspective view of a second example of the thermoelectric conversion module component according to the fifth embodiment of the present invention.

FIG. 39 is a perspective view of a thermoelectric conversion module according to the fifth embodiment of the present invention.

FIG. 40 is a part plan view of a first modification of the meandering pattern of pn junction pairs.

FIG. 41 is a part plan view of a second modification of the meandering pattern of the pn junction pairs.

FIG. 42 is a part plan view of a third modification of the meandering pattern of the pn junction pairs.

FIG. 43 is a part plan view of a fourth modification of the meandering pattern of the pn junction pairs.

FIG. 44 is a part plan view of a fifth modification of the meandering pattern of the pn junction pairs.

FIG. 45 is a part plan view of a sixth modification of the meandering pattern of the pn junction pairs.

FIG. 46 is a part plan view of a seventh modification of the meandering pattern of the pn junction pairs.

FIG. 47 is a part plan view of an eighth modification of the meandering pattern of the pn junction pairs.

### REFERENCE NUMERALS

2, 2x joint surface;

surface (to be inner periphery);

10, 10f laminate;

11, 11f, 11P, 11q, 11r thermoelectric element;

12, 12f insulating layer;

13, 13k p-type thermoelectric material layer;

14, 14k n-type thermoelectric material layer;

external electrode;

first lead portion;

second lead portion;

relay conductive layer;

21, 22 outer peripheral electrode;

23, 24 external lead pad;

25, 25a, 25b, 26, 27 via hole;

circuit-less laminate;

insulating block;

32a upper portion;

32b middle portion;

32c lower portion;

33, 34 lead exposed portion;

block;

bonding portion;

pipe;

81a, 81b cutting-plane line;

stacking direction;

extending direction;

85a, 85b cutting-plane line;

91, 92 arrow;

101, 102, 102a, 102b, 102c, 104, 105, 106, 107, 108, 131, 132 thermoelectric conversion module component;

201, 202, 203, 204, 205, 207, 208, 232, 301 thermoelectric conversion module

### DETAILED DESCRIPTION OF THE INVENTION

The terms “thermoelectric conversion module component” and “thermoelectric conversion module” are used in this specification. The term “thermoelectric conversion module component” is used to indicate one component configured to constitute the “thermoelectric conversion module”.

### First Embodiment

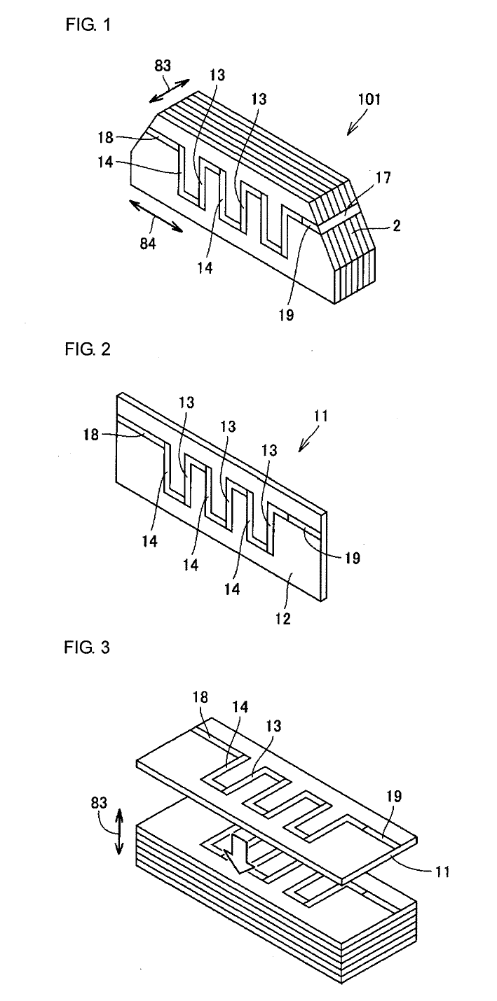

A thermoelectric conversion module component and a thermoelectric conversion module according to a first embodiment of the present invention will be described with reference to FIGS. 1 to 11.

As shown in FIG. 1, a thermoelectric conversion module component 101 according to this embodiment includes a laminate formed of a plurality of stacked thermoelectric elements each including a unit circuit having repeated pn junction pairs that extend meanderingly and that are formed of p-type thermoelectric material layers and n-type thermoelectric material layers arranged so as to be alternately connected to each other on a surface of an insulating layer. The thermoelectric conversion module component 101 further includes oblique joint surfaces 2 at which electrodes are led out of the laminate, the joint surfaces 2 being such that a plurality of the thermoelectric conversion module components are connected by contacting the surfaces with each other to form a ring as a whole and are electrically connected to each other. As with the thermoelectric conversion module component 101 according to this embodiment, the fact that the joint surfaces 2 are arranged as surfaces extending parallel to the stacking direction 83 of the thermoelectric elements is one preferred form.

A method for producing a thermoelectric conversion module component according to this embodiment includes the steps of forming a thermoelectric element including a unit circuit having repeated pn junction pairs that extend meanderingly and that are formed of p-type thermoelectric material layers and n-type thermoelectric material layers arranged so as to be alternately connected to each other on a surface of an insulating layer, stacking a plurality of the thermoelectric elements to form a laminate, forming oblique joint surfaces by cutting off corners of the laminate obliquely, the oblique joint surfaces being such that a plurality of the laminates are connected by contacting the surfaces with each other to form a ring as a whole and are electrically connected to each other, and sintering the laminate.

For the method for producing a thermoelectric conversion module component according to this embodiment, in the step of forming the oblique joint surfaces, preferably, cutting is obliquely performed in such a manner that the joint surfaces are formed as surfaces extending parallel to the stacking direction of the thermoelectric elements.

The method for producing a thermoelectric conversion module component will be described in detail by taking the thermoelectric conversion module component 101, shown in FIG. 1, as an example. As shown in FIG. 2, p-type thermoelectric material layers 13 and n-type thermoelectric material layers 14 are alternately connected to each other on a surface of an insulating layer 12 to form a unit circuit having repeated pn junction pairs that extend meanderingly, which is defined as a thermoelectric element 11. The insulating layer 12 may be formed of a ceramic green sheet. More specifically, the insulating layer 12 may be formed of, for example, a Ba—Al—Si—O-based ceramic green sheet. The p-type thermoelectric material layers 13 and the n-type thermoelectric material layers 14 can be arranged in desired patterns on the surface of the insulating layer 12 by screen printing with respective paste materials. To form the p-type thermoelectric material layers 13, for example, a Cu paste may be applied by printing. To form the n-type thermoelectric material layers 14, for example, a constantan paste may be applied by printing.

A first lead portion 18 and a second lead portion 19 composed of conductive materials are formed at both ends of the unit circuit having repeated pn junction pairs that extend meanderingly. The term “unit circuit” is used to indicate the amount of a circuit arranged on the surface of the insulating layer 12 that is formed of a single layer and a single sheet. The first lead portion 18 and the second lead portion 19 are formed so as to extend to the respective ends of the insulating layer 12. The first lead portion 18 and the second lead portion 19 may be formed by screen printing with appropriate metal paste.

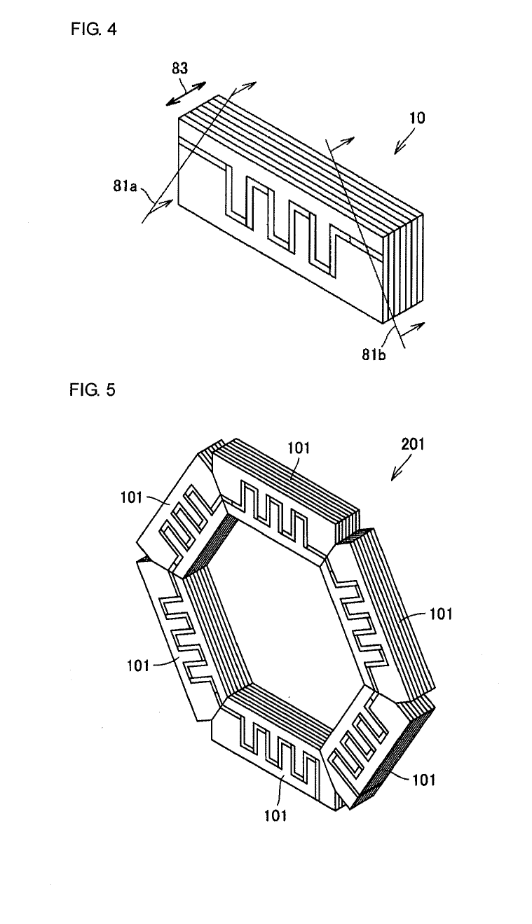

A plurality of the resulting thermoelectric elements 11 are stacked to form a block-shaped laminate as shown in FIG. 3, thereby forming a laminate 10 as shown in FIG. 4. However, in the case where the laminate 10 is formed as a rectangular parallelepiped, a step of cutting off corners along cutting-plane lines 81a and 81b is performed as shown in FIG. 4 after the stacking, thereby forming the joint surfaces 2. Furthermore, the metal paste is applied onto the joint surfaces 2 so as to cross all layers in a direction parallel to a stacking direction 83, forming external electrodes 17 extending in the stacking direction 83 as shown in FIG. 1. On one joint surface 2, a corresponding one of the external electrodes 17 is formed so as to connect the first lead portions 18 of all the layers. On the other joint surface 2, the corresponding external electrode 17 is formed so as to connect the second lead portions 19 of all the layers. If one thermoelectric conversion module component is formed by stacking m thermoelectric elements 11, the formation of the external electrodes 17 as described above allows the one thermoelectric conversion module component to correspond to a component in which m unit circuits are connected in parallel.

Then sintering is performed to provide the thermoelectric conversion module component 101 as shown in FIG. 1. Here, after the rectangular insulating layers 12 are stacked to form the laminate in the form of a rectangular parallelepiped, the two corners are cut off. Alternatively, the laminate may be formed by stacking hexagonal insulating layers in which the two corners of each of the rectangles have been cut off. In this case, the step of cutting off the two corners after the stacking is not necessary. Note that cutting off two corners after the stacking advantageously forms the reliably flat joint surfaces 2 with high accuracy.

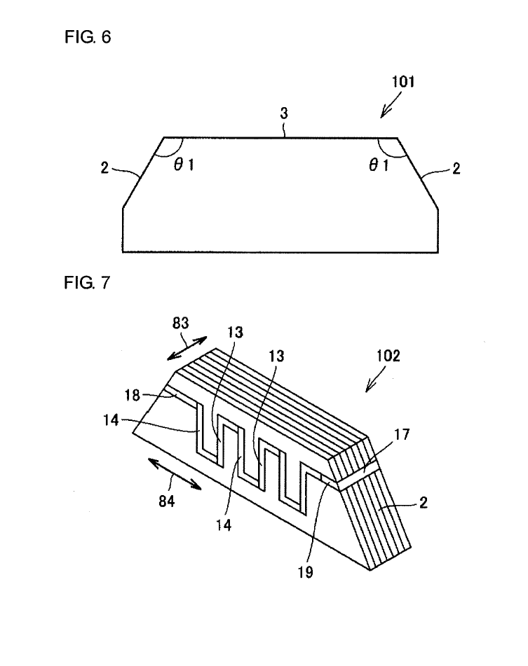

In the thermoelectric conversion module component 101 shown in FIG. 1, the joint surfaces 2 are arranged as surfaces at which electrodes are led out of the laminate; hence, the first lead portion 18 and the second lead portion 19 are arranged so as to reach the joint surfaces 2. The thermoelectric conversion module component 101 includes the joint surfaces 2 arranged obliquely with respect to an extending direction 84 of the unit circuits that extend meanderingly. The formation of the oblique joint surfaces 2 enables a plurality of thermoelectric conversion module components 101 to be connected by contacting the surfaces with each other to form a ring as a whole, as shown in FIG. 5, and to be electrically connected to each other. In the case where the joint surfaces 2 are contacted with each other, the external electrodes 17 face and are contacted with each other, thereby reliably establishing the electrical connection between adjacent thermoelectric conversion module components 101. A structure shown in FIG. 5 corresponds to one thermoelectric conversion module 201.

In the thermoelectric conversion module 201, a plurality of the thermoelectric conversion module components 101 are connected to each other to form a ring as a whole, and a plurality of the unit circuits are connected to each other so as to form a substantially polygonal shape in such a manner that sides on which the unit circuits extend are arranged along the perimeter of the ring.

In this embodiment, how many thermoelectric conversion module components are combined to form a ring in order to produce one thermoelectric conversion module is not particularly limited. In the case where six thermoelectric conversion module components 101 are connected to form a ring as shown in FIG. 5, the angles of the joint surfaces 2 are determined in such a manner that angles θ1 are 120° as shown in FIG. 6. The angles θ1 are the interior angles of both corners of a surface 3 that constitutes the inner periphery of the ring when the components are connected. In FIG. 6, the circuit arranged on the surface of the thermoelectric conversion module is not shown. The value of the angle θ1 is appropriately determined by the number of thermoelectric conversion module components to form one ring. In the case where one ring is constituted by n thermoelectric conversion module components, θ1 is expressed as (90+180/n)° where n represents an integer of 3 or more.

In the case where a plurality of the thermoelectric conversion module components are combined to assemble a ring-shaped thermoelectric conversion module, in order to bond the joint surfaces 2 to each other, the joint surfaces 2 may be bonded to each other with, for example, glass-containing silver paste or a conductive adhesive. The type of bonding medium may be selected in consideration of what degree of high temperature that can be reached under the intended service conditions of the thermoelectric conversion module. If the temperature can reach as high as about 600° C., the glass-containing silver paste is preferably used. If the temperature rises only to about 100° C., the conductive adhesive may be used. This idea is also applicable to the following embodiments.

The thermoelectric conversion module component 101 shown in FIG. 1 is in the form of a hexagonal prism in which a hexagon formed by cutting off two corners of a rectangle extends in the stacking direction 83. A thermoelectric conversion module component according to this embodiment may be in the form of a quadratic prism in which a left-right symmetric trapezoid extends in the stacking direction 83, like a thermoelectric conversion module component 102 shown in FIG. 7.

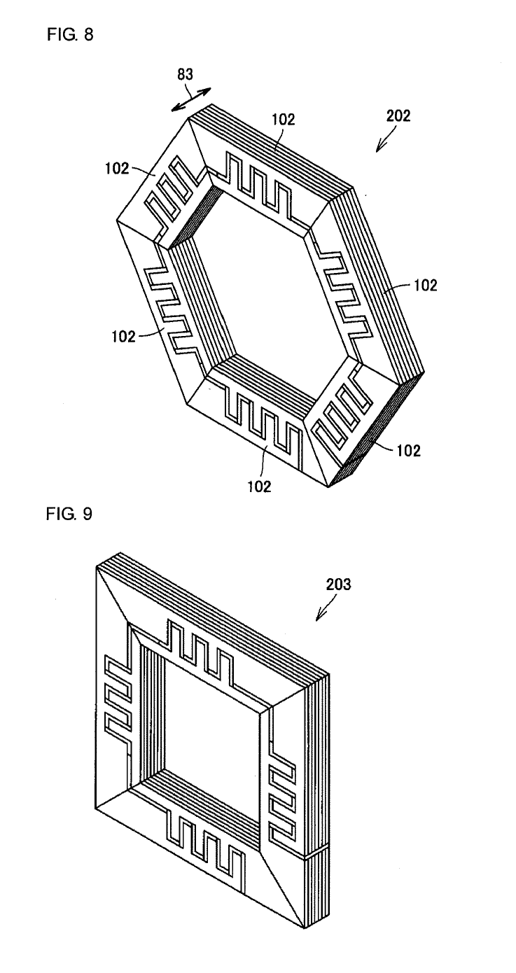

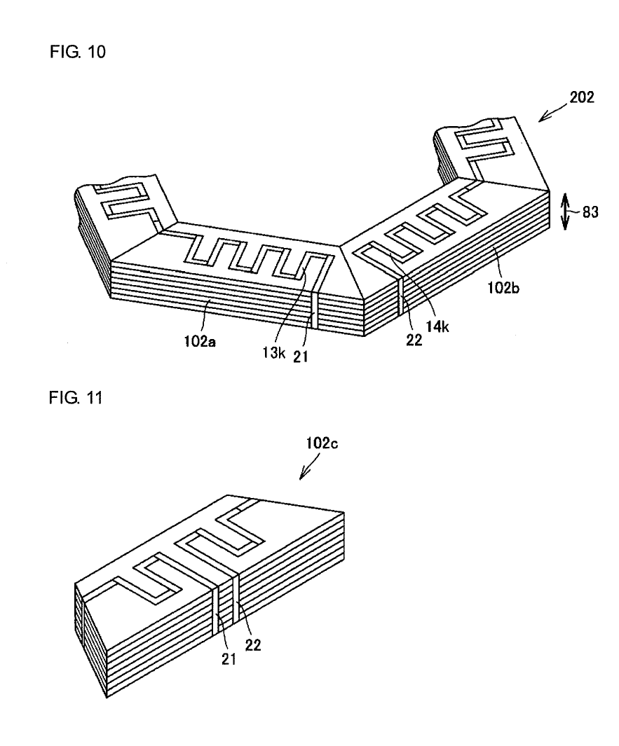

FIG. 8 shows a ring formed by combining six thermoelectric conversion module components 102. The article shown in FIG. 8 is a thermoelectric conversion module 202. As a modification, four components formed by changing the angles and the dimensions of the joint surfaces 2 of the thermoelectric conversion module components 102 may be combined as shown in FIG. 9, thereby affording a ring. The ring-shaped article shown in FIG. 9 is a thermoelectric conversion module 203.

Note that in any thermoelectric conversion module, strictly speaking, the ring is not formed by connecting only a plurality of thermoelectric conversion module components having exactly the same structure. It is necessary to arrange at least a pair of external terminals. The term “external terminals” is used to indicate terminals configured to draw current from a ring-shaped thermoelectric conversion module when the ring-shaped thermoelectric conversion module is assembled. FIG. 10 shows an example in which external electrodes are arranged in one place in the middle of the ring of the thermoelectric conversion module 202. In this example, long outer peripheral electrodes 21 and 22 extending in the stacking direction 83 of the insulating layers are arranged as the external terminals on the outer periphery. In the thermoelectric conversion module components used in this place, in order to establish connection with the outer peripheral electrodes 21 and 22, slightly different printed wiring patterns are arranged on the insulating layers. In FIG. 10, leads extend from p-type thermoelectric material layers 13k and n-type thermoelectric material layers 14k arranged on adjacent thermoelectric conversion module components 102a and 102b not to adjacent thermoelectric conversion module components but to an outer peripheral surface for connection. All the insulating layers hidden in the inside have the same wiring as that on the uppermost visible insulating layer. The outer peripheral electrodes 21 and 22 are electrically connected to ends of the leads extending to the outer peripheral surface on all the insulating layers.

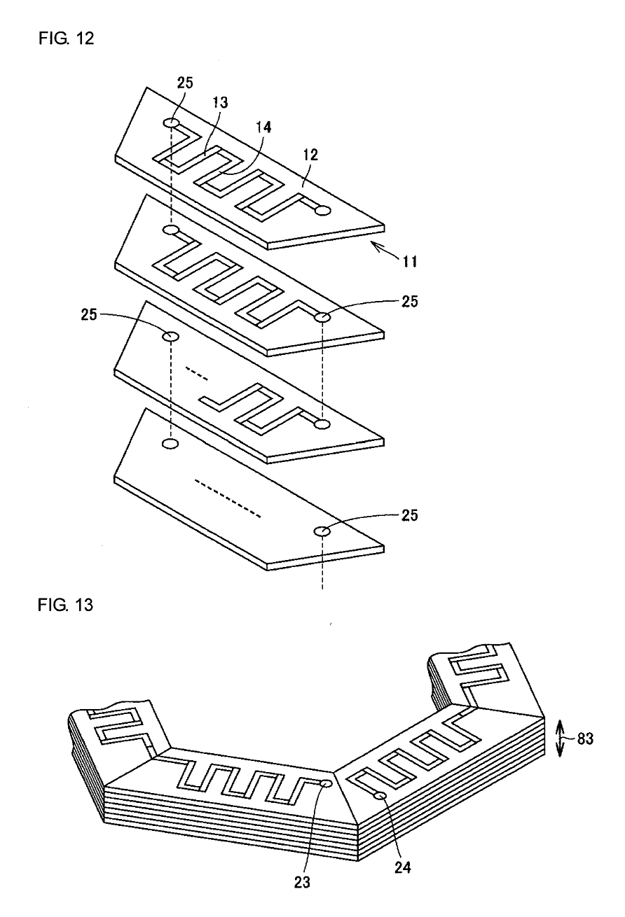

In the case where the number of the thermoelectric conversion module components constituting one thermoelectric conversion module is n and where the number of stacked insulating layers in one thermoelectric conversion module component is m, in this thermoelectric conversion module, two thermoelectric conversion module components having the external terminals are connected to a circuit formed of n-2 thermoelectric conversion module components connected in series, each of the thermoelectric conversion module components including m unit circuits connected in parallel, thereby forming a closed ring in appearance. A current is drawn through the external terminals. FIG. 10 shows an example in which the outer peripheral electrodes 21 and 22 serving as external terminals are separately arranged on the two thermoelectric conversion module components. Alternatively, the two outer peripheral electrodes 21 and 22 may be arranged in one thermoelectric conversion module component 102c as shown in FIG. 11. In this manner, only one thermoelectric conversion module component 102c may be incorporated in one thermoelectric conversion module, and the others may be the thermoelectric conversion module components 102 without the external terminal, which is advantageous. In this case, one thermoelectric conversion module component having the external terminals is connected to a circuit formed of n-1 thermoelectric conversion module components connected in series, each of the thermoelectric conversion module components including m unit circuits connected in parallel, thereby forming a closed ring. A current is drawn through the external terminals.

In the thermoelectric conversion module according to this embodiment, about n×m unit circuits are included in one thermoelectric conversion module. A current can be drawn from all the unit circuits in the thermoelectric conversion module. In this embodiment, each thermoelectric conversion module component includes the external electrodes 17, so that m unit circuits are connected in parallel. Alternatively, in place of m unit circuits connected in parallel, it is also possible to connect m unit circuits in series in one thermoelectric conversion module component by the appropriately arranging via holes. In this case, for example, it is conceivable that via holes 25 are alternately arranged in the laminate and that the front ends and the rear ends of the unit circuits are alternately arranged for each layer as shown in FIG. 12. The appropriate use of the via holes and the external electrodes through the entirety of the thermoelectric conversion module enables us to design any combination of connections of about n×m unit circuits. In other words, whether the unit circuits are connected in parallel, series, or both can be freely designed by the appropriate use of the via holes and the external electrodes. A higher proportion of series connection in the thermoelectric conversion module results in a reduction in current and an increase in voltage taken from the module. A higher proportion of parallel connection results in a reduction in voltage and an increase in current taken from the module. The combination of the series connection and the parallel connection in the thermoelectric conversion module may be appropriately selected according to the purpose.

The type of external terminal is not limited to the outer peripheral electrode as shown in FIGS. 10 and 11. For example, as shown in FIG. 13, via holes are arranged in portions of thermoelectric conversion module components at which electrodes are led to the outside, the via holes penetrating in the thickness direction, and external lead pads 23 and 24 exposed at the uppermost surfaces or the lowermost surfaces may be used as external terminals. In this case, a current can be drawn through the external lead pads 23 and 24.

A combination of the plural thermoelectric conversion module components according to this embodiment simply results in a ring. The term “a combination of the plural thermoelectric conversion module components” used here includes a combination of the plural thermoelectric conversion module components including thermoelectric conversion module components provided with external terminals required.

The plural thermoelectric conversion module components are combined to form a ring, thereby assembling one thermoelectric conversion module. The thermoelectric conversion module according to this embodiment is formed by contacting the joint surfaces of the thermoelectric conversion module components. It is thus possible to easily establish electrical connection between the thermoelectric conversion module components through the joint surfaces and to form a structure in which the thermoelectric conversion module components are supported by each other using the joint surfaces, thereby providing the reliable thermoelectric conversion module having a simple ring structure that is not easily broken by impact as a whole.

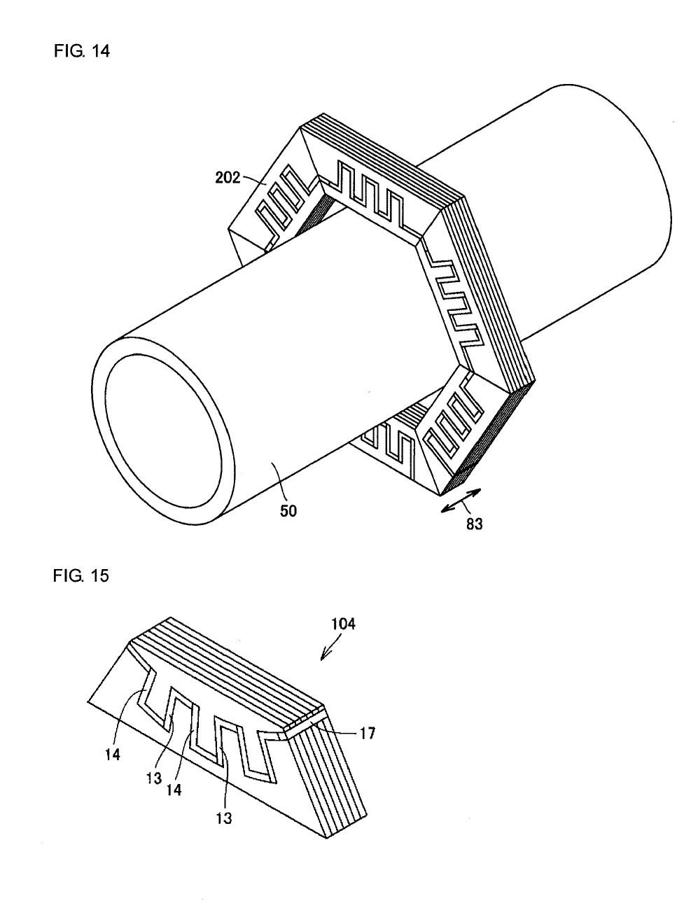

In particular, the thermoelectric conversion module according to this embodiment has a ring shape as a whole and thus can be installed so as to surround a pipe 50 as shown in FIG. 14. FIG. 14 shows an exemplary case where the thermoelectric conversion module 202 is installed. In the case where the pipe 50 serves as a high- or low-temperature heat source, a temperature difference develops between the inner periphery near the pipe 50 and the outer periphery remote from the pipe 50 of the ring-shaped thermoelectric conversion module 202. Thus, a voltage is generated by the action of each of the pn junction pairs in the thermoelectric conversion module 202. Current-drawing terminals (not shown) are arranged on the thermoelectric conversion module 202, so that a current can be drawn to the outside. That is, thermal energy that has been wastefully released from the pipe to surroundings in the past is converted into electric energy by the use of the thermoelectric conversion module according to the present invention and is effectively used. The thermoelectric conversion module component according to the present invention is useful to easily assemble such a thermoelectric conversion module.

### Second Embodiment

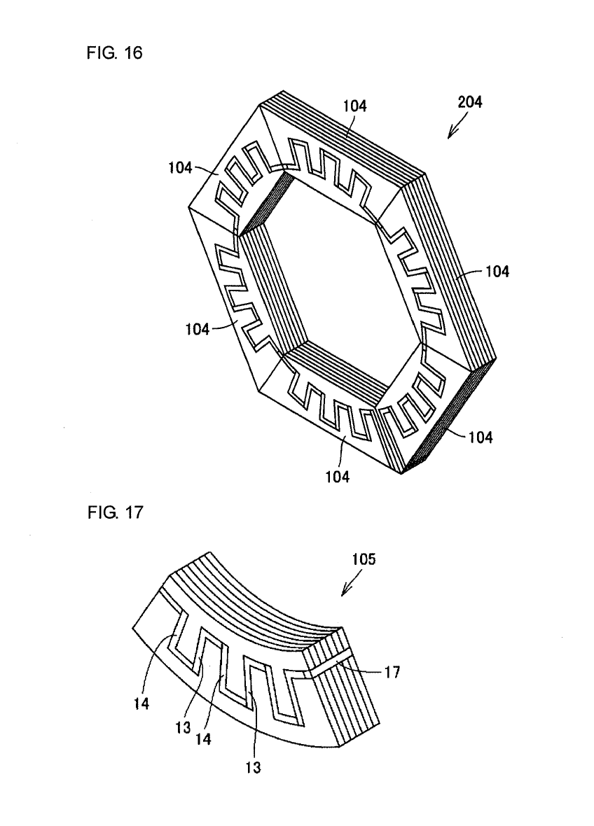

A thermoelectric conversion module component and a thermoelectric conversion module according to a second embodiment of the present invention will be described with reference to FIGS. 15 and 16. While a thermoelectric conversion module component 104 according to this embodiment is basically common to that described in the first embodiment, the arrangement of a unit circuit is different. In the thermoelectric conversion module component 104, the unit circuit extends arcuately as shown in FIG. 15. A plurality of the thermoelectric conversion module components 104 are combined to provide a thermoelectric conversion module 204 as shown in FIG. 16.

The thermoelectric conversion module 204 is formed by connecting the plural thermoelectric conversion module components 104 to form a ring as a whole, and the plural unit circuits are connected so as to form a substantially circular shape along the perimeter of the ring.

In this embodiment, the same effect as that in the first embodiment is also provided. Furthermore, in this embodiment, the unit circuits are circular. Thus, in the case where the plural thermoelectric conversion module components are combined to form a ring-shaped thermoelectric conversion module, while the outside shape of the thermoelectric conversion module is polygonal, the connected circuits can be circular. Accordingly, a temperature gradient produced by a heat source such as a pipe arranged in the center is more efficiently reflected, generating electric energy.

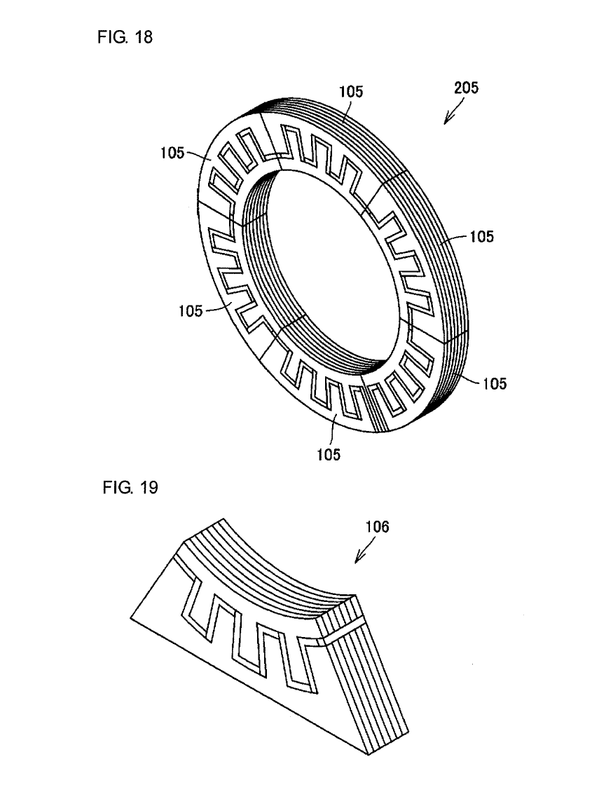

More preferably, the outside shape of the thermoelectric conversion module component, which is a laminate, is arcuate as in the case of a thermoelectric conversion module component 105 shown in FIG. 17. In this manner, a combination of a plurality of the components provides a thermoelectric conversion module 205 as shown in FIG. 18. If this structure can be used, the thermoelectric conversion module can surround a pipe while in closer contact with the periphery of the pipe, so that a temperature gradient can be more efficiently utilized to generate electric energy. In this case, the outside shape of each thermoelectric conversion module component need not be completely arcuate. As with a thermoelectric conversion module component 106 shown in FIG. 19, when only a side to be formed into an inner peripheral surface is arcuate, the component provides the effect to some extent. This is because the shape of the inner peripheral surface is important in establishing close contact with the pipe and thus the outer peripheral surface need not necessarily be cylindrical.

Alternatively, in cases where only the outside shape of a thermoelectric conversion module component is arcuate, like the thermoelectric conversion module component 105 (see FIG. 17) according to this embodiment, with a unit circuit arranged linear as described in the first embodiment and where only a side of the outside shape of a thermoelectric conversion module component to be formed into an inner peripheral surface is arcuate, like the thermoelectric conversion module component 106 (see FIG. 19) according to this embodiment, with a unit circuit arranged linear as described in the first embodiment, such modules provide the effect to some extent. In such cases, it is possible to provide the effect of achieving stability by close contact with a pipe. However, if conditions permit, it is preferred that the unit circuit be arcuately arranged as initially described in this embodiment.

### Third Embodiment

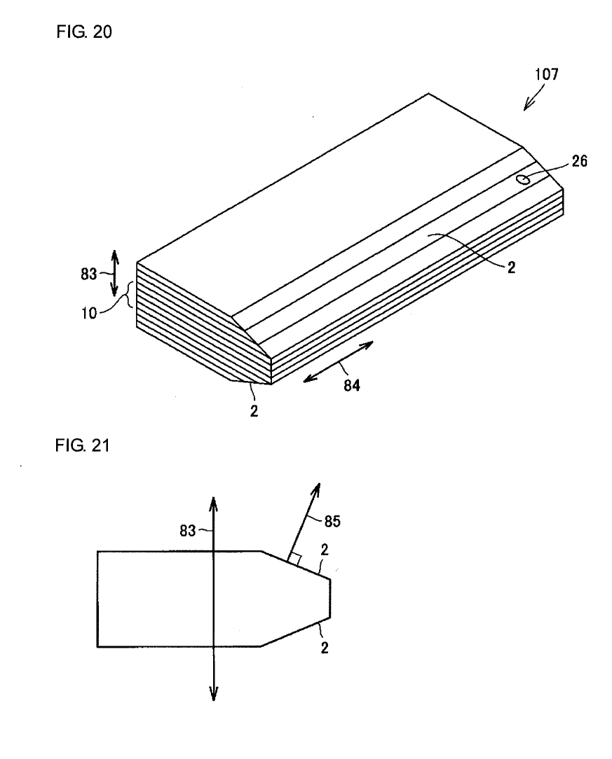

A thermoelectric conversion module component and a thermoelectric conversion module according to a third embodiment of the present invention will be described with reference to FIGS. 20 to 29. FIG. 20 shows a thermoelectric conversion module component 107 according to this embodiment. The thermoelectric conversion module component 107 also includes the laminate 10 formed of a plurality of stacked thermoelectric elements 11 each including a unit circuit having repeated pn junction pairs that extend meanderingly and that are formed of the p-type thermoelectric material layers 13 and the n-type thermoelectric material layers 14 arranged so as to be alternately connected to each other on a surface of the insulating layer 12. Furthermore, the thermoelectric conversion module component 107 also includes oblique joint surfaces 2 at which electrodes are led out of the laminate, the joint surfaces 2 being such that a plurality of the thermoelectric conversion module components are connected by contacting the surfaces with each other to form a ring as a whole and are electrically connected to each other.

While no unit circuit is visible on the uppermost surface of the thermoelectric conversion module component 107, the laminate 10 formed of the stacked thermoelectric elements 11 having the unit circuits is contained therein. The laminate 10 includes the elements stacked in the stacking direction 83. The meandering unit circuit of each of the thermoelectric elements 11 extends in the extending direction 84.

As shown in FIG. 21, in the thermoelectric conversion module component 107, the joint surfaces 2 are arranged as surfaces each having a normal 85 that obliquely intersects the stacking direction 83 of the thermoelectric elements. The normal 85 is a geometrically assumable imaginary line to check the direction of each joint surface 2. In FIG. 21, the joint surfaces 2 are arranged on the upper and lower sides. The joint surfaces 2 are symmetrically arranged at two corners.

For a method for producing a thermoelectric conversion module component according to this embodiment, in a step of forming the oblique joint surfaces, cutting is obliquely performed in such a manner that the joint surfaces are formed as surfaces each having a normal that obliquely intersects the stacking direction of the thermoelectric elements.

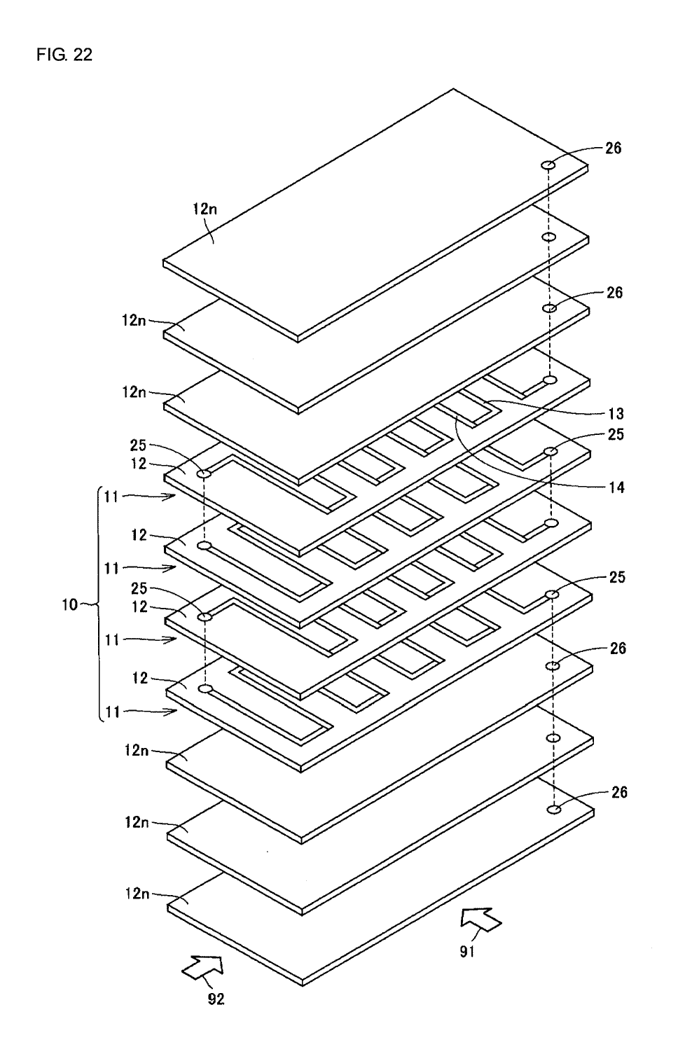

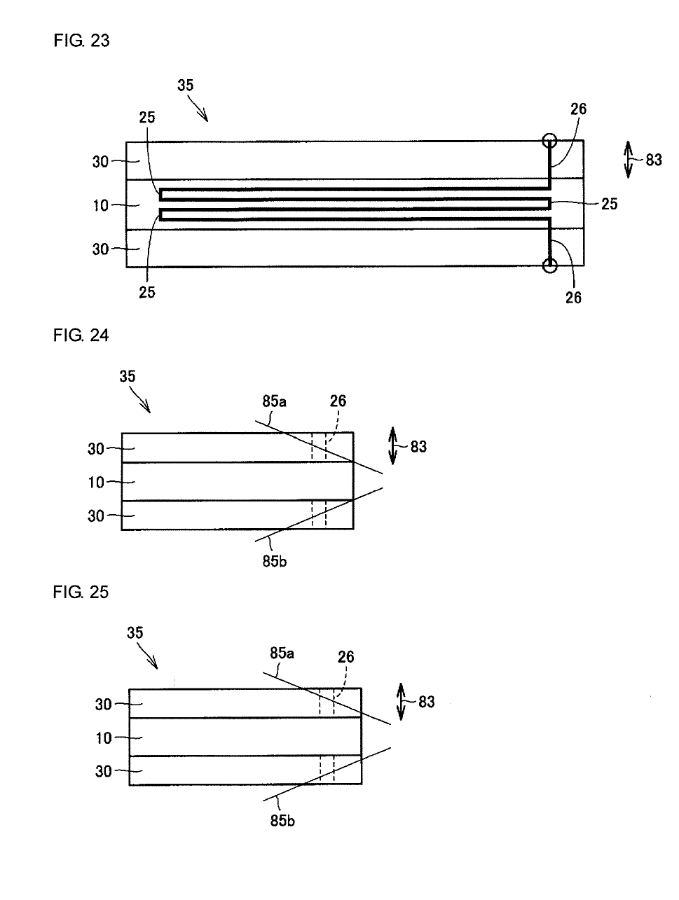

The method for producing a thermoelectric conversion module component will be described by taking the thermoelectric conversion module component 107, shown in FIG. 20, as an example. The thermoelectric conversion module component 107 is formed by stacking the plural thermoelectric elements 11 and plural insulating layers 12n in combination, as shown in FIG. 22. The thermoelectric element 11 is a sheet-like structure including the unit circuit having repeated pn junction pairs that extend meanderingly and that are formed of the p-type thermoelectric material layers 13 and the n-type thermoelectric material layers 14 arranged so as to be alternately connected to each other on a surface of the insulating layer 12, as described in the first embodiment. Each of the insulating layers 12n is an insulating layer that do not have a unit circuit but have only a via hole 26. The insulating layers 12n may be ceramic green sheets that are not provided with a circuit. A portion where the thermoelectric elements 11 are continuously stacked corresponds to the laminate 10. For the thermoelectric conversion module component 107, a portion to be formed into the laminate 10 is arranged in a midsection, and the plural insulating layers 12n are arranged on each of the upper side and the lower side of the midsection. Bunches of the insulating layers 12n arranged on the upper and lower sides are referred to as “circuit-less laminates 30”. Stacking is performed in such a manner that the laminate 10, i.e., a bunch of the thermoelectric elements 11, arranged in the midsection is sandwiched by the circuit-less laminates 30 arranged on the upper and lower sides as a whole. Each of the thermoelectric elements 11 has the via holes 25. All the layers are alternately electrically connected. Assuming that the laminate 10 includes m thermoelectric elements 11, in an example shown in FIG. 22, the laminate 10 in its entirety corresponds to m unit circuits connected in series. Each of the via holes 26 passes through a corresponding one of the circuit-less laminates 30 arranged on the upper and lower sides, so that a current can be drawn through pads exposed at the upper and lower sides of the laminate 10. FIG. 23 shows an outline of an inner circuit when a stacked state in its entirety is viewed from an arrow 91 shown in FIG. 22. In the circuit-less laminates 30 arranged on the upper and lower sides, electrodes are linearly led out through the via holes 26 in the stacking direction 83. In the laminate 10 arranged in the midsection, the unit circuits are connected in series through the via holes 25 so as to form a meandering shape. Each of the unit circuits has a meandering shape in plan on a surface of a corresponding one of the thermoelectric elements 11. For the case of the stacking structure shown in FIG. 23, the circuits has a meandering shape also in the thickness direction.

In this way, the plural thermoelectric elements 11 and the plural insulating layers 12n are stacked in combination to form a block 35 as a whole, the block 35 being an integral laminate in which one laminate 10 is arranged between two circuit-less laminates 30 as shown in FIG. 24. FIG. 24 shows a stacked state in its entirety when viewed from an arrow 92 shown in FIG. 22. The block 35 shown in FIG. 24 is subjected to cutting to form the joint surfaces 2. The cutting is performed along cutting-plane lines 85a and 85b that are set so as to obliquely traverse the circuit-less laminates 30 and so as not to traverse the laminate 10. Thus, the via holes 26 passing through the circuit-less laminates 30 are obliquely cut, thereby always exposing the cut ends of the via holes 26 at newly produced joint surfaces 2 as shown in FIG. 20. Note that in the case where the circuit-less laminates 30 are obliquely cut without a margin in the thickness direction, if the deviation of the cutting positions occurs, the laminate 10 is also cut. Thus, for the sake of safety, the cutting-plane lines 85a and 85b may be slightly apart from the laminate 10 as shown in FIG. 25.

In any case, the block 35 is subjected to cutting in this way to form the joint surfaces 2, and then sintering is performed, affording the thermoelectric conversion module component 107 as shown in FIG. 20.

In the thermoelectric conversion module component 107 shown in FIG. 20, the joint surfaces 2 are arranged surfaces at which electrodes are led out of the laminate 10. Thus, as described above, the via holes 26 are exposed. The thermoelectric conversion module component 107 has the joint surfaces 2 arranged parallel to the extending direction 84 of the unit circuit that extends meanderingly. The formation of the oblique joint surfaces 2 enables a plurality of the thermoelectric conversion module components 107 to be connected by contacting the surfaces with each other to form a ring as a whole, as shown in FIG. 26, and to be electrically connected to each other. In the case where the joint surfaces 2 are contacted with each other, the exposed portions of the via holes 26 face and are contacted with each other, thereby reliably establishing the electrical connection between adjacent thermoelectric conversion module components 107. A structure shown in FIG. 26 corresponds to a thermoelectric conversion module 207.

In the thermoelectric conversion module 207, a plurality of the thermoelectric conversion module components 107 are connected to each other to form a ring as a whole, and sides on which the unit circuits extend lie in a direction parallel to the central axis of the ring.

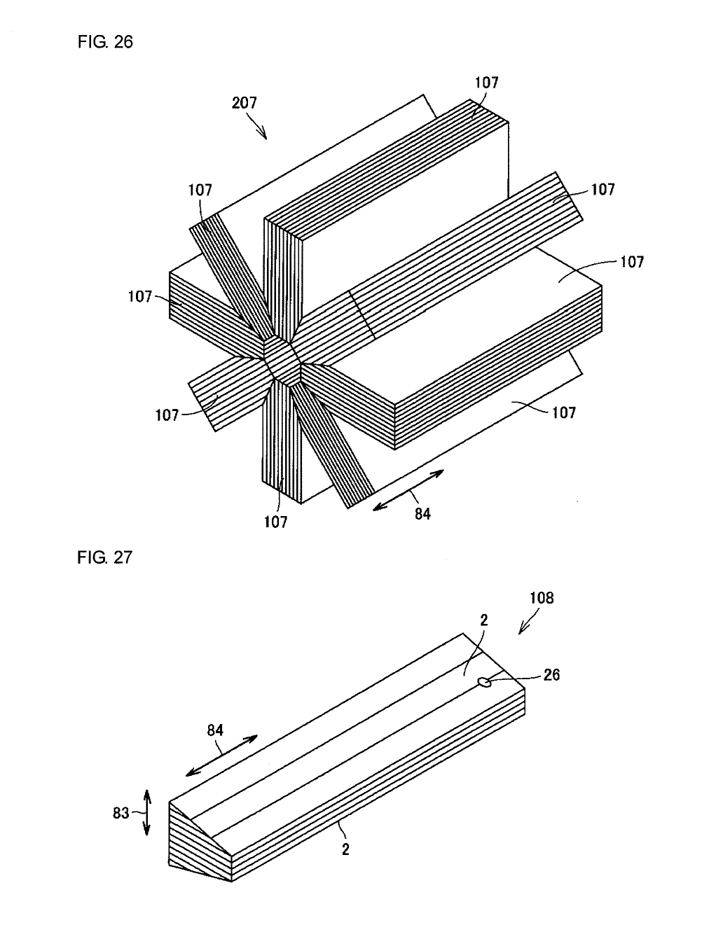

The thermoelectric conversion module component 107 shown in FIG. 20 is in the form of a hexagonal prism in which a hexagon formed by cutting off two corners of a rectangle extends in the extending direction 84. A thermoelectric conversion module component according to this embodiment may be in the form of a quadratic prism in which a left-right symmetric trapezoid extends in the extending direction 84, like a thermoelectric conversion module component 108 shown in FIG. 27.

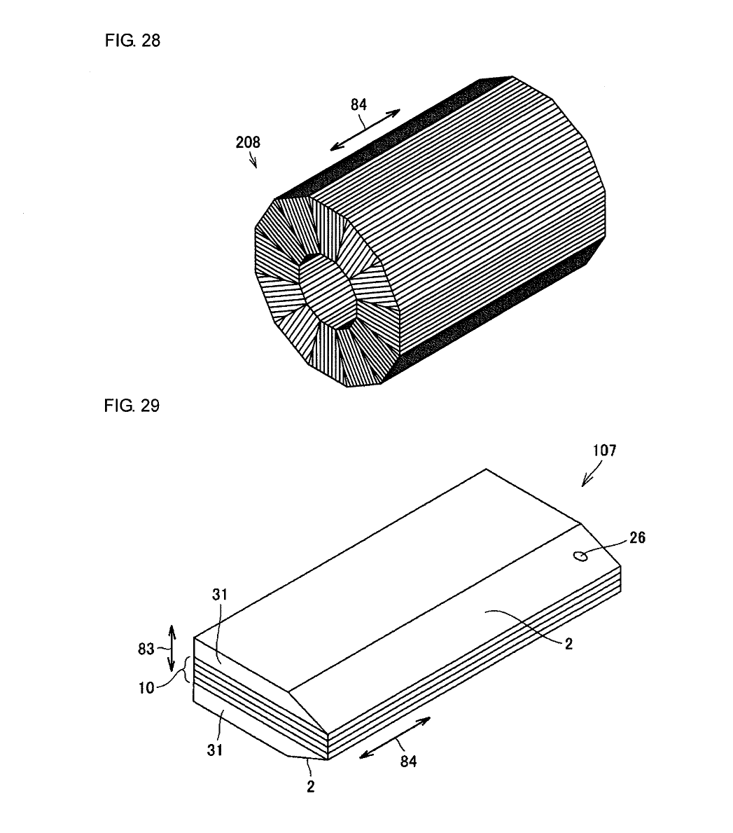

FIG. 28 shows a ring formed by combining 12 thermoelectric conversion module components 108 shown in FIG. 27. The article shown in FIG. 28 is a thermoelectric conversion module 208. Also in this embodiment, how many thermoelectric conversion module components are combined to form a ring in order to produce one thermoelectric conversion module is not particularly limited. In the case where one thermoelectric conversion module is constituted by n thermoelectric conversion module components, n is an integer of 3 or more. The slope of each joint surface 2 is appropriately determined by the number of thermoelectric conversion module components to form one ring.

In each of FIGS. 26 and 28, the details are not illustrated. For a thermoelectric conversion module, in order to draw a generated current to the outside, at least one pair of external terminals is arranged at any portion in the prismatic or substantially cylindrical structure. The external terminals may be appropriately arranged by the use of the structure of the outer peripheral electrodes in which a conductive material is attached to the sides of the laminates or pads in which ends of the via holes are exposed, as described in the first embodiment.

In this embodiment, the circuit-less laminates 30 including the stacked insulating layers 12n are arranged in the upper and lower portions of the thermoelectric conversion module component. Alternatively, sufficiently thick insulating blocks may be arranged on these portions in place of the circuit-less laminates 30. For example, in the thermoelectric conversion module component 107 shown in FIG. 20, a structure in which the laminate 10 is sandwiched between two insulating blocks 31 may be used as shown in FIG. 29, provided that each of the insulating blocks 31 has a via hole 26 passing therethrough in the thickness direction.

Also in this embodiment, the same effect as that described in the first embodiment is basically provided. For the thermoelectric conversion module according to this embodiment, m unit circuits are connected in series in one thermoelectric conversion module component. The thermoelectric conversion module components are connected to each other by contacting the via holes 26 with each other exposed at the joint surfaces 2. This also makes it possible to connect the thermoelectric conversion module components to each other in series, so that about m×n unit circuits are connected in series in the entirety of the thermoelectric conversion module. A current can be drawn from all the unit circuits in the thermoelectric conversion module.

As described in the first embodiment, also in this embodiment, the appropriate use of the via holes and the external electrodes through the entirety of the thermoelectric conversion module enables us to design any combination of connections of about n×m unit circuits. In other words, whether the unit circuits are connected in parallel, series, or both can be freely designed by the appropriate use of the via holes and the external electrodes. Accordingly, the same effect as that described in the first embodiment can be provided.

That is, the thermoelectric conversion module according to this embodiment can also be installed so as to surround a pipe in the same way as in the thermoelectric conversion module described in the first embodiment. FIG. 30 shows an example of a state in which the thermoelectric conversion module 207 is installed so as to surround the pipe 50.

As described above, the thermoelectric conversion module according to the present invention includes a ring formed by connecting thermoelectric conversion module components having any structure according to any of the foregoing embodiments. The term “ring” includes a tube. Furthermore, the term “ring” includes an article having a substantially circular contour in cross section and an article having a substantially polygonal contour in cross section.

A method for producing a thermoelectric conversion module according to the present invention includes the steps of preparing a plurality of thermoelectric conversion module components having any structure according to any of the foregoing embodiments, and connecting the plural thermoelectric conversion module components to form a ring.

A method for producing a thermoelectric conversion module according to the present invention includes the steps of producing a plurality of thermoelectric conversion module components by the method for producing a thermoelectric conversion module component according to any of the foregoing embodiments, and connecting the resulting plural thermoelectric conversion module components to form a ring.

Hereinafter, the thermoelectric conversion modules according to the first and second embodiments are referred to as “thermoelectric conversion module type 1”, and the thermoelectric conversion modules according to the third embodiment is referred to as “thermoelectric conversion module type 2”. They share a common feature in that in each type, the plural thermoelectric conversion module components each including the laminate formed by stacking the plural thermoelectric elements are combined to form a ring-shaped three-dimensional structure. They have different advantages when they are installed so as to surround pipes.

For the thermoelectric conversion module type 1, the extending direction 84 of each of the unit circuits lies along the circumferential direction of the pipe. Thus, the pipe can be surrounded by a small number of the thermoelectric conversion module components. Furthermore, a large-sized pipe can also be easily surrounded. The thermoelectric conversion module type 1 is capable of locally producing electric energy from a temperature difference in a short section and thus has the advantage that it is easily installed even for a short linear portion of a serpentine pipe.

For the thermoelectric conversion module type 2, the extending direction 84 of each of the unit circuits lies along the longitudinal direction of the pipe. An increase in the length of the unit circuit enables the length of the pipe in the longitudinal direction to increase easily. Thus, the thermoelectric conversion module type 2 is suited to cover a long section of the pipe. The thermoelectric conversion module type 2 is capable of locally arranging a large number of the unit circuits near the central portion even for the case of a short circumference and thus is advantageous in producing electric energy from a temperature difference around a pipe with a small diameter.

For each of the type 1 and the type 2, in the case of installation on a pipe, the thermoelectric conversion module may be assembled in advance without the pipe, and then the thermoelectric conversion module may be fitted around the pipe when piping is installed. Alternatively, the number of the separate thermoelectric conversion module components required may be transported to an installation site, and then the thermoelectric conversion module components are combined so as to surround the pipe on the site to assemble the thermoelectric conversion module.

### Fourth Embodiment

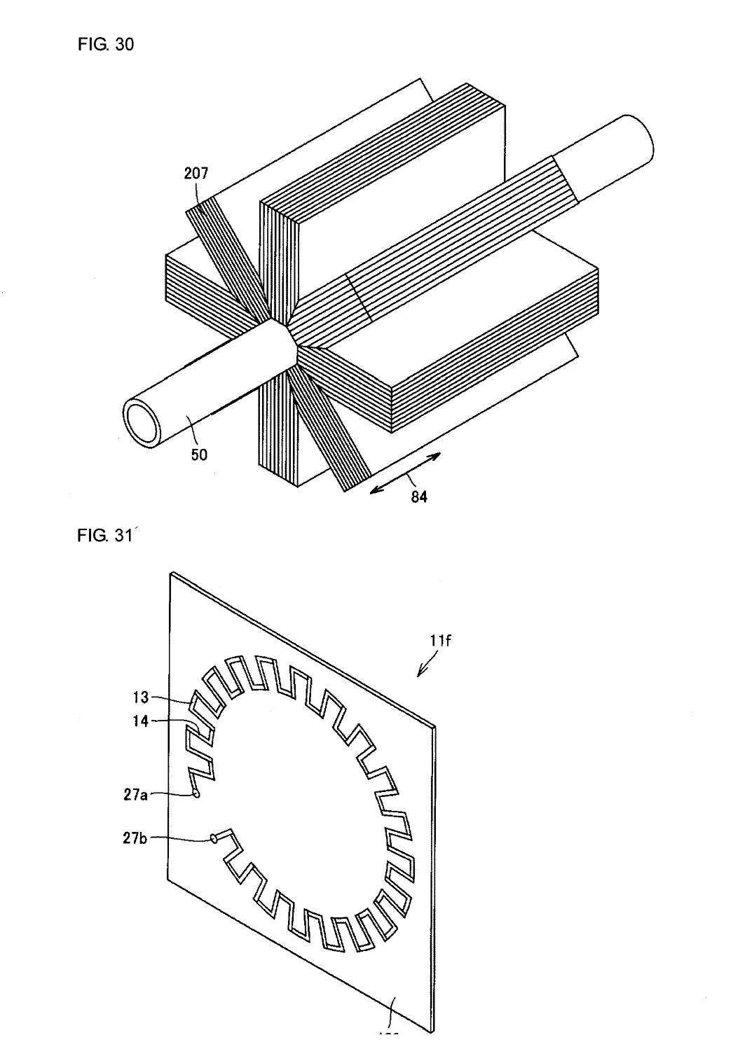

A thermoelectric conversion module according to a fourth embodiment of the present invention will be described with reference to FIGS. 31 to 34. In each of the first to third embodiments, a combination of the plural thermoelectric conversion module components produces one thermoelectric conversion module. In contrast, in this embodiment, the stacking of thermoelectric elements directly produces a thermoelectric conversion module. The thermoelectric conversion module according to this embodiment is an annular block-shaped laminate formed of a plurality of stacked thermoelectric elements each including a ring-shaped unit circuit having repeated pn junction pairs that extend meanderingly and that are formed of p-type thermoelectric material layers and n-type thermoelectric material layers arranged so as to be alternately connected to each other on a surface of an insulating layer to form a substantially ring shape.

A method for producing a thermoelectric conversion module according to this embodiment will first be described. The method for producing a thermoelectric conversion module includes the steps of forming a thermoelectric element including a ring-shaped unit circuit having repeated pn junction pairs that extend meanderingly and that are formed of p-type thermoelectric material layers and n-type thermoelectric material layers arranged so as to be alternately connected to each other on a surface of an insulating layer to form a substantially ring shape, forming an annular block-shaped laminate by stacking a plurality of the thermoelectric elements, and sintering the laminate.

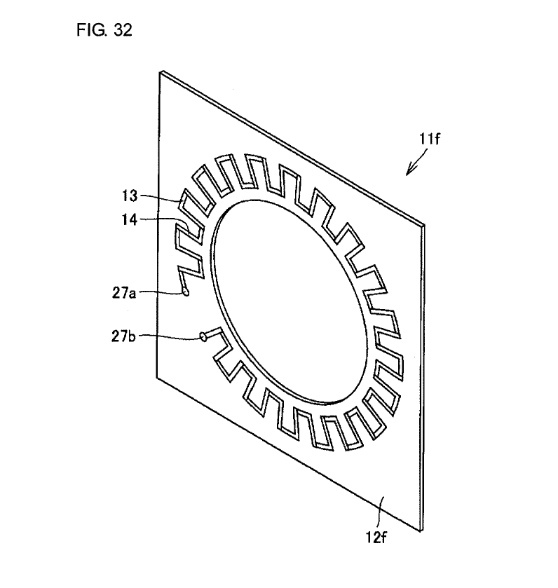

The method for producing a thermoelectric conversion module will be described below by means of specific examples. As shown in FIG. 31, a ring-shaped unit circuit is formed on a surface of a substantially square insulating layer 12f, the ring-shaped unit circuit having repeated pn junction pairs that extend meanderingly and that are formed of p-type thermoelectric material layers 13 and n-type thermoelectric material layers 14 arranged so as to be alternately connected to each other to form a substantially ring shape. This can be formed by arranging the p-type thermoelectric material layers 13 and the n-type thermoelectric material layers 14 by screen printing. The ring-shaped unit circuit is not a complete ring but has a break. Via holes 27a and 27b are arranged at both ends at the break. A sheet-like article having such a structure is defined as a thermoelectric element 11f. As shown in FIG. 32, a circular hole is punched in the inner portion of the ring-shaped unit circuit of the thermoelectric element 11f. Next, a plurality of the thermoelectric elements 11f are stacked to form a laminate 10f as shown in FIG. 33. The stacking is performed in such a manner that all the via holes 27a and 27b in all layers are aligned and that the via holes 27a and 27b pass continuously through the laminate 10f in the stacking direction 83. Here, the central circular hole is formed, and then the stacking is performed. Alternatively, the order of the steps may be reversed. That is, the central circular hole may be formed after the stacking. This order of the steps is preferred because a smoother inner peripheral surface is formed. That is, in the method for producing a thermoelectric conversion module, the step of forming an annular block-shaped laminate preferably includes the substeps of stacking the plural thermoelectric elements and then punching a central hole.

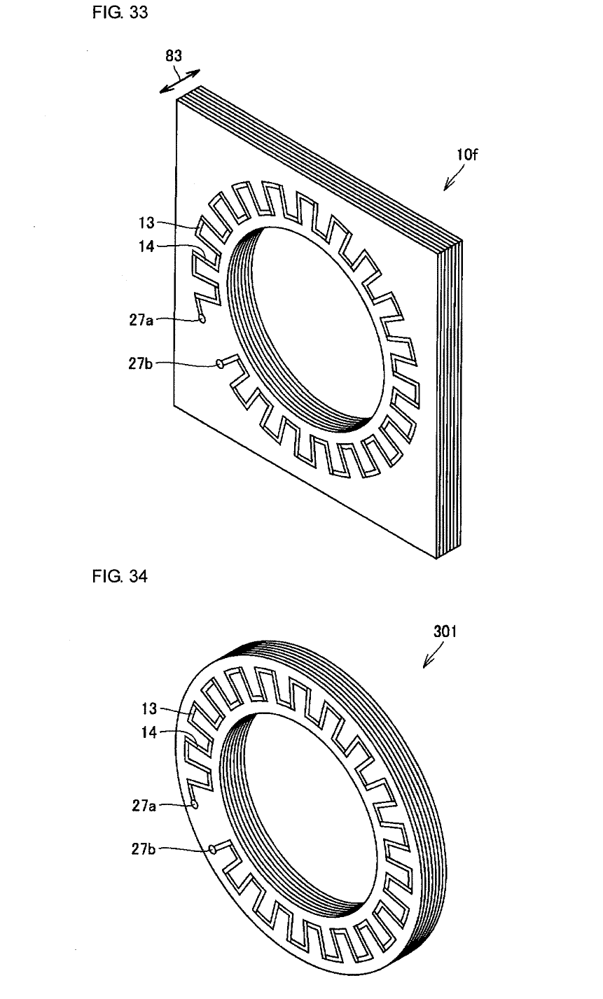

The laminate shown in FIG. 33 may be sintered to complete a thermoelectric conversion module. As shown in FIG. 34, an unnecessary part in a peripheral portion is preferably removed by cutting or the like. In an example shown in FIG. 34, the outer peripheral surface is also a cylindrical surface. The laminate shown in FIG. 34 is sintered to complete a thermoelectric conversion module 301 according to this embodiment.

Alternatively, an unnecessary part in the peripheral portion of the single layer before the stacking may be cut off, and then the stacking may be performed.

In this embodiment, the simple stacking of the thermoelectric elements including the predetermined circuit arranged by printing on the surface of the insulating layer produces the ring-shaped thermoelectric conversion module, thus eliminating the need to assemble thermoelectric conversion module components and permitting easy handling. The thermoelectric conversion module 301 according to this embodiment is installed so as to surround a heat source such as a pipe and is capable of converting a temperature difference obtained from the heat source into electric energy to be taken. Electric energy can be taken through the via holes 27a and 27b exposed at the surface. In this embodiment, however, the via holes 27a and 27b are merely taken as an example. Electric energy may be taken through external terminals according to another embodiment.

According to this embodiment, it is possible to produce the reliable thermoelectric conversion module having a simple structure that is not easily broken by impact.

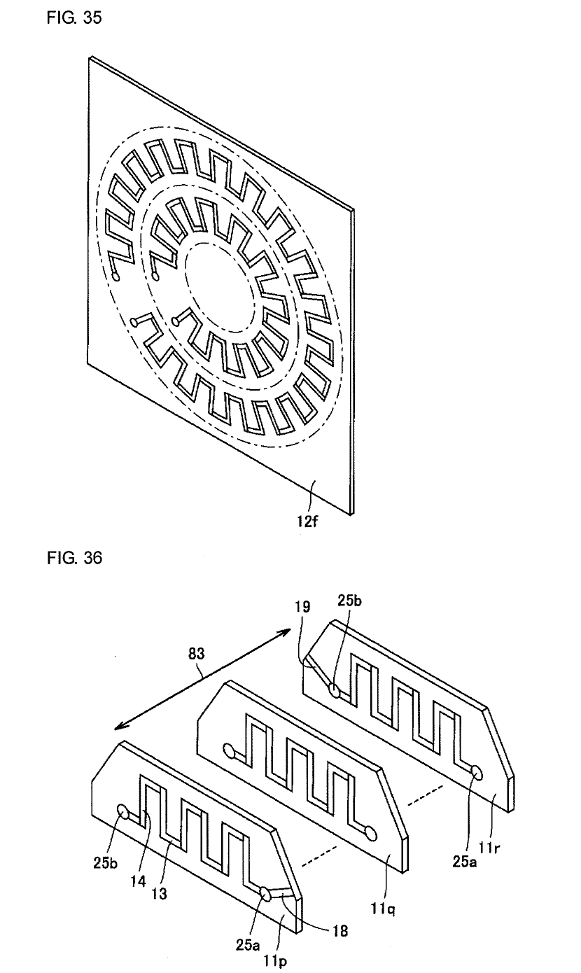

The substep of punching a circular hole in the inner portion of the ring-shaped unit circuit in the course of production is included in this embodiment. At this time, a disk-like member resulting from the punching operation, i.e., a punched scrap, may be discarded. However, it is also possible to make effective use of a portion to be punched scrap. To that end, a plurality of ring-shaped unit circuits with different diameters may be concentrically formed in the insulating layer 12f as shown in FIG. 35. The formation can be performed by screen printing. Plural punching operations are performed along alternate long and short dash lines shown in FIG. 35 to effectively provide inner and outer ring-shaped unit circuits, thereby reducing the punched scrap. In this case, it is possible to reduce a wasted portion of the entirety of the insulating layer 12f, resulting in a reduction in cost. It is also possible to simultaneously produce thermoelectric elements used for the manufacture of different thermoelectric conversion modules having different diameters.

In the method for producing a thermoelectric conversion module, preferably, the step of forming a thermoelectric element includes a substep of concentrically forming a plurality of unit circuits on the surface of the insulating layer and performing concentric cutting to provide different-sized thermoelectric elements, the step of forming an annular block-shaped laminate includes a substep of stacking the different-sized thermoelectric elements in each size, and in the sintering step, each of the resulting laminates from the different-sized thermoelectric elements is sintered.

FIG. 35 shows an example in which two ring-shaped unit circuits are concentrically arranged. Alternatively, three or more ring-shaped unit circuits may be concentrically arranged. Furthermore, the contour shape of the ring-shaped unit circuit is not limited to a circular shape. Even if ring-shaped unit circuits each have a polygonal contour, an elliptical contour, or the like, the concentric arrangement of the ring-shaped unit circuits permits the same operation to be performed.

### Fifth Embodiment

A thermoelectric conversion module component and a thermoelectric conversion module according to a fifth embodiment of the present invention will be described with reference to FIGS. 36 and 37.

In the first and second embodiments, the joint surfaces 2 arranged to connect the thermoelectric conversion module components to each other have exposed external electrodes 17 (see FIGS. 1, 7, 15, and 17). The electrodes exposed at the joint surfaces 2 are not limited to such electrodes extending throughout the entire length in the stacking direction 83. For example, electrodes according to this embodiment may be used. FIG. 36 is an exploded view of a thermoelectric conversion module component according to this embodiment. The thermoelectric conversion module component is produced by stacking a predetermined number of thermoelectric elements 11p, a predetermined number of thermoelectric elements 11q, and a predetermined number of thermoelectric elements 11r, and performing sintering. In the thermoelectric elements 11p, 11q, and 11r, unit circuits arranged are the same, and common via holes 25a and 25b passing through all layers in order to establish electrical connection are arranged at both ends of each of the unit circuits. These elements are different in the presence or absence of lead portions electrically connected to the via holes. In each of the thermoelectric elements 11p, the first lead portion 18 is arranged to connect the via hole 25a to an oblique side. However, in each of the thermoelectric elements 11q and the thermoelectric elements 11r, such a lead portion is not arranged. In each of the thermoelectric elements 11r, the second lead portion 19 is arranged to connect the via hole 25b to an oblique side. However, in each of the thermoelectric elements 11p and the thermoelectric elements 11q, such a lead portion is not arranged. FIG. 37 shows an article formed by stacking all layers in the combination shown in FIG. 36 and performing sintering. This article is a thermoelectric conversion module component 131 according to this embodiment. A plurality of the thermoelectric elements 11p are stacked in an upper portion 32a of the thermoelectric conversion module component 131. A plurality of the thermoelectric elements 11q are stacked in a middle portion 32b. A plurality of the thermoelectric elements 11r are stacked in a lower portion 32c.

For the thermoelectric conversion module component 131 according to this embodiment, the plural first lead portions 18 are exposed at one of the joint surfaces 2 in the upper portion 32a, so that a plurality of ends of the first lead portions 18 combine to form a lead exposed portion 33. The plural second lead portions 19 are exposed at the other joint surface 2 in the lower portion 32c, so that a plurality of end of the second lead portions 19 combine to form a lead exposed portion 34. Each of the lead exposed portions 33 and 34 is exposed at only a small portion of a corresponding one of the joint surfaces 2. In this way, they may only be exposed at such a local portions. Even if the lead exposed portions are misaligned and thus do not face directly when adjacent thermoelectric module components are connected to form a ring, electrical connection can be established by applying a conductive adhesive medium as described in the first embodiment onto the entirety of the joint surfaces 2 and then performing bonding. That is, no matter where the electrodes are exposed at the joint surfaces 2 facing each other, if only the electrodes are exposed somewhere on the joint surfaces, electrical connection can be easily established. This can also be true for misalignment between the external electrodes 17 shown in FIGS. 1, 7, and so forth.

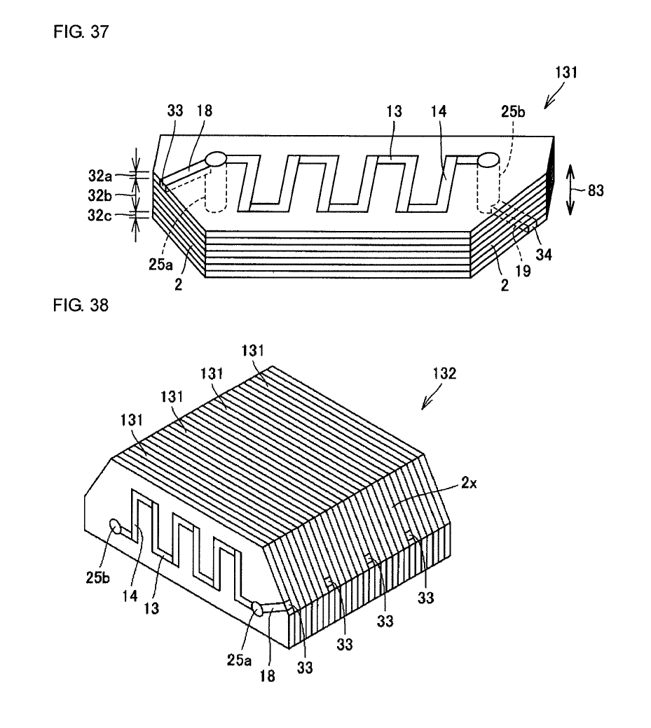

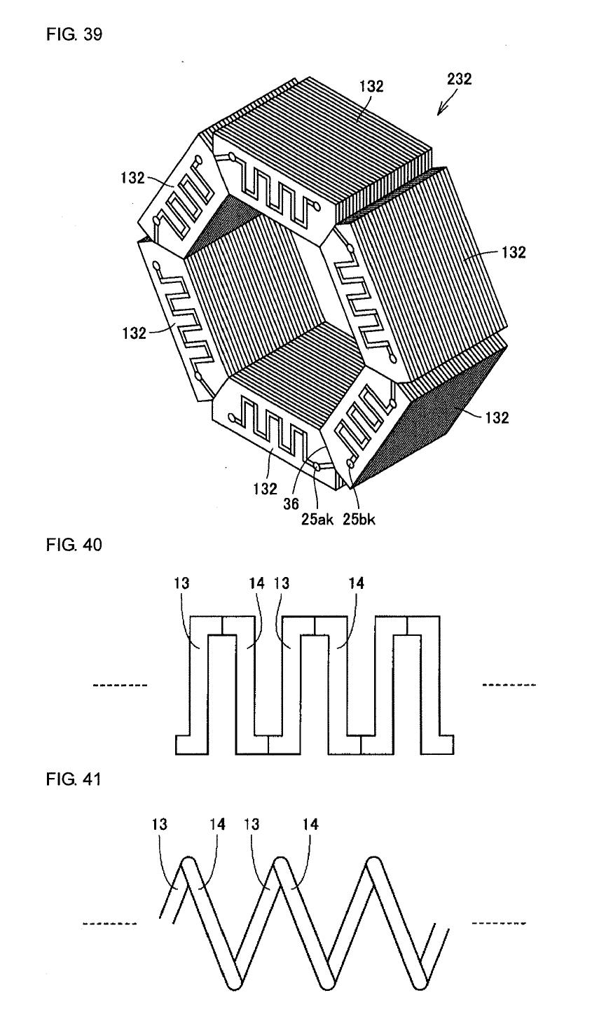

A plurality of the thermoelectric conversion module components 131 shown in FIG. 37 may be stacked in the stacking direction 83 and then used. FIG. 38 shows the stack. This serves as a thermoelectric conversion module component 132. In this case, wide joint surfaces 2x can be provided. A plurality of the thermoelectric conversion module components 132 having an increased thickness may be assembled to form a ring, thereby resulting in one thermoelectric conversion module. In this case, it is also possible to facilitate the production of a thermoelectric conversion module capable of covering a long section of a pipe.

A thermoelectric conversion module according to this embodiment is produced by combining the plural thermoelectric conversion module components 131 or the plural thermoelectric conversion module components 132 to form a ring or cylinder. FIG. 39 shows an example of a thermoelectric conversion module 232 according to this embodiment. In this case, the joint surfaces 2x may be bonded in such a manner that electrical connection is not established at only one bonding portion 36 and that bonding is performed with a conductive adhesive medium at the other bonding portions. In this case, via holes 25ak and 25bk adjacent to both sides of the bonding portion 36 are not electrically connected. Thus, portions where the 25ak and 25bk are exposed can be used as external terminals without any processing.

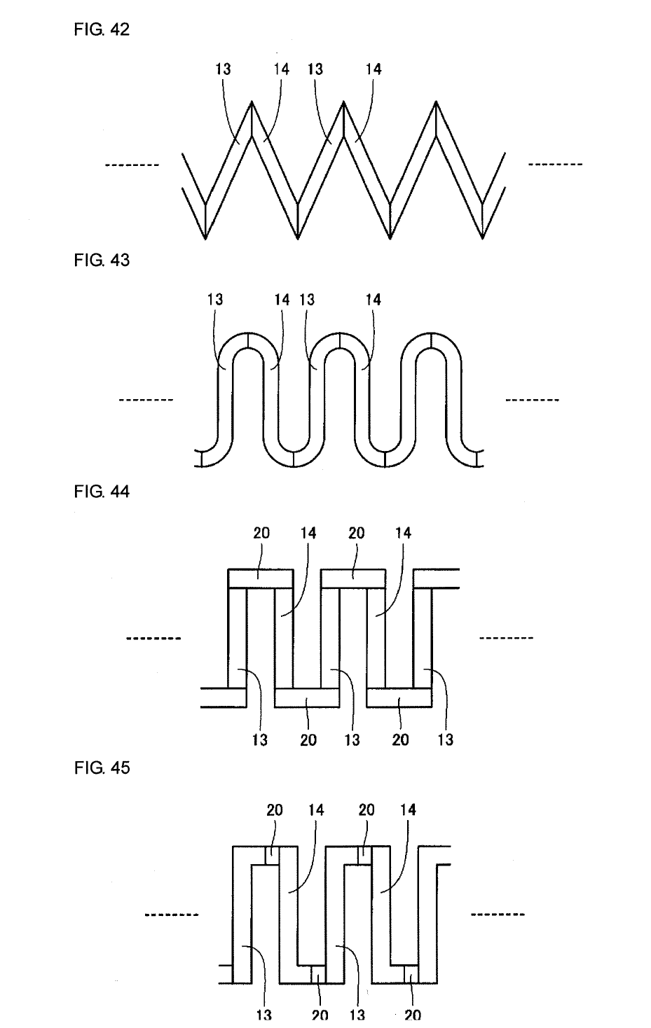

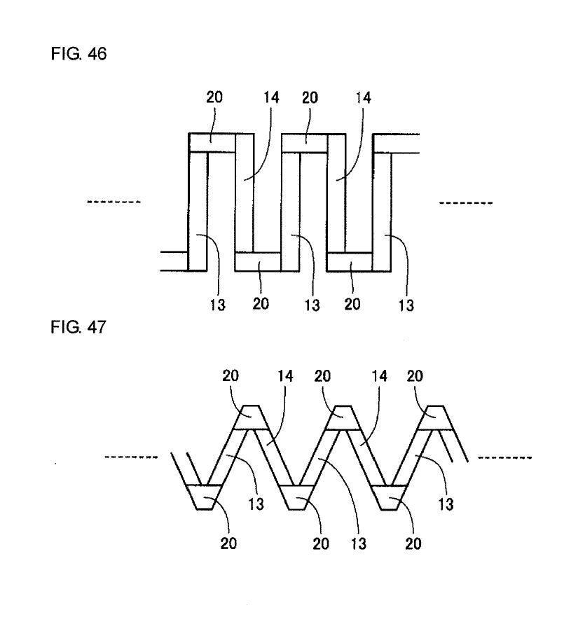

In each of the foregoing embodiments, the pn junction pairs in the unit circuit are repeated pn junction pairs that extend meanderingly and that are formed of the L-shaped p-type thermoelectric material layers 13 and the L-shaped n-type thermoelectric material layers 14 arranged so as to be alternately directly contacted. Alternatively, other meandering patterns may be used. For example, patterns shown in FIGS. 40 to 43 may be used. Furthermore, the p-type thermoelectric material layers 13 and the n-type thermoelectric material layers 14 need not be directly connected but may be connected with conductive layers provided therebetween. That is, a meandering pattern in which the p-type thermoelectric material layers 13 and the n-type thermoelectric material layers 14 are alternately connected with relay conductive layers 20 provided therebetween may be used, as shown in FIGS. 44 to 47.

In each of the foregoing embodiments, for the sake of convenience, in the drawings, the number of turns in the circuit, the number of stacking insulating layers, the number of thermoelectric conversion module components required to assemble one ring, and so forth are small numbers that are easy to understand. In fact, these numbers may be large numbers, for example, several tens, several hundreds, or several thousands of numbers.

In each of the foregoing embodiments, the ring-shaped thermoelectric conversion module formed by assembling the thermoelectric conversion module components is exemplified. The thermoelectric conversion module need not be in the form of a closed ring but may be in the form of a “C-shape”, in which part of a circumference is cut off, “semicircumference”, which is one half a circumference, and so forth. For these cases, the effect can be provided to some extent so long as appropriate external terminals are arranged to draw a current. Depending on a clearance around a pipe, the bias of a temperature difference produced, and so forth, it may be preferable to assemble and install the thermoelectric conversion module having a shape in which part of a circumference is cut off rather than the closed ring. The term “closed ring” defined here is used to indicate a shape that forms a perimeter without a break. That is, it includes circles, ellipses, ovals, and polygons, such as triangles, quadrangles, pentagons, and hexagons.

Unless specific circumstances exist, the thermoelectric conversion module preferably has a closed ring shape so as to surround the entire perimeter of a pipe because the module can be stably installed. For the case where the thermoelectric conversion module has a closed ring shape, a temperature difference can be effectively used over the entire perimeter of a pipe, which is preferable.

It should be understood that the embodiment and examples disclosed herein are illustrative and non-restrictive in every respect. The scope of the present invention is defined by the scope of the claims, rather than the description above, and is intended to include any modifications within the scope and meaning equivalent to the scope of the claims.

The present invention is applicable to a thermoelectric conversion module component, thermoelectric conversion module, and methods for producing the aforementioned.

1. A thermoelectric conversion module component comprising:
a laminate having of a plurality of stacked thermoelectric elements, each thermoelectric element including:
a unit circuit having repeated pn junction pairs that extend meanderingly and that are formed of p-type thermoelectric material layers and n-type thermoelectric material layers arranged so as to be alternately connected to each other on a surface of an insulating layer; and
oblique joint surfaces along opposed end surfaces of the laminate and at which electrodes lead out of the laminate, the oblique joint surfaces being configured such that a plurality of the thermoelectric conversion module components may be connected together by contacting the oblique joint surfaces of adjacent ones of the plurality of thermoelectric conversion module components with each other to form a ring such that the plurality of thermoelectric conversion module components are electrically connected to each other.

2. The thermoelectric conversion module component according to claim 1, wherein the joint surfaces are arranged as surfaces extending parallel to a stacking direction of the thermoelectric elements.

3. The thermoelectric conversion module component according to claim 2, wherein the unit circuit extends arcuately.

4. The thermoelectric conversion module component according to claim 1, wherein the oblique joint surfaces are arranged as surfaces each having a normal that obliquely intersects a stacking direction of the thermoelectric elements.

5. A thermoelectric conversion module comprising a plurality of the thermoelectric conversion module components according to claim 1, the thermoelectric conversion module components being connected to each other to form a ring.

6. A thermoelectric conversion module) comprising a plurality of the thermoelectric conversion module components according to claim 2, the thermoelectric conversion module components being connected to each other to form a ring, and a plurality of the unit circuits being connected to each other so as to form a substantially polygonal shape such that sides on which the unit circuits extend are arranged along a perimeter of the ring.

7. A thermoelectric conversion module comprising a plurality of the thermoelectric conversion module components according to claim 3, the thermoelectric conversion module components being connected to each other to form a ring, and a plurality of the unit circuits being connected to form a substantially circular shape along a perimeter of the ring.

8. A thermoelectric conversion module comprising a plurality of the thermoelectric conversion module components according to claim 4, the thermoelectric conversion module components being connected to each other to form a ring, and sides on which the unit circuits extend extending in a direction parallel to a central axis of the ring.

9. A thermoelectric conversion module comprising:
an annular block-shaped laminate having a plurality of stacked thermoelectric elements, each thermoelectric element including a ring-shaped unit circuit having repeated pn junction pairs that extend meanderingly and that are formed of p-type thermoelectric material layers and n-type thermoelectric material layers arranged so as to be alternately connected to each other on a surface of an insulating layer to form a substantially ring shape.

10. A method for producing a thermoelectric conversion module component, the method comprising:
forming a thermoelectric element including a unit circuit having repeated pn junction pairs that extend meanderingly and that are formed of p-type thermoelectric material layers and n-type thermoelectric material layers arranged so as to be alternately connected to each other on a surface of an insulating layer;
stacking a plurality of the thermoelectric elements to form a laminate;
forming oblique joint surfaces on the laminate, the oblique joint surfaces being configured such that a plurality of the laminates may be connected by contacting the oblique joint surfaces of adjacent ones of the laminates with each other to form a ring such that the laminates are electrically connected to each other; and
sintering the laminate.

11. The method for producing a thermoelectric conversion module component according to claim 10, wherein the oblique joint surfaces are formed by cutting the laminate in such a manner that the joint surfaces are formed as surfaces that extend in parallel to a stacking direction of the thermoelectric elements.

12. The method for producing a thermoelectric conversion module component according to claim 10, wherein the oblique joint surfaces are formed by cutting the laminate in such a manner that the joint surfaces are formed as surfaces each having a normal that obliquely intersects a stacking direction of the thermoelectric elements.

13. A method for producing a thermoelectric conversion module, the method comprising:
preparing a plurality of the thermoelectric conversion module components according to claim 1; and
connecting the plurality of thermoelectric conversion module components together to form a ring.

14. A method for producing a thermoelectric conversion module, the method comprising:
producing a plurality of thermoelectric conversion module components by the method for producing a thermoelectric conversion module component according to claim 10; and
connecting the resulting plural thermoelectric conversion module components together to form a ring.

15. A method for producing a thermoelectric conversion module, the method comprising:
forming a thermoelectric element including a ring-shaped unit circuit having repeated pn junction pairs that extend meanderingly and that are formed of p-type thermoelectric material layers and n-type thermoelectric material layers arranged so as to be alternately connected to each other on a surface of an insulating layer to form a substantially ring shape;
forming an annular block-shaped laminate by stacking a plurality of the thermoelectric elements; and
sintering the laminate.

16. The method for producing a thermoelectric conversion module according to claim 15, wherein the step of forming an annular block-shaped laminate includes the substeps of stacking the plural thermoelectric elements and punching a central hole.

17. The method for producing a thermoelectric conversion module according to claim 15, wherein the step of forming a thermoelectric element includes a substep of concentrically forming a plurality of unit circuits on the surface of the insulating layer and performing concentric cutting to provide a plurality of different-sized thermoelectric elements,
the step of forming an annular block-shaped laminate includes a substep of stacking the plurality of different-sized thermoelectric elements in each size, and
in the sintering step, sintering each of the resulting laminates in each stacked size.
